(19) United States
(12) Patent Application Publication
(10) Pub. No.: US 2025/0259612 A1
(43) Pub. Date: Aug. 14, 2025

(54) ACTIVE DRIVING SOUND EFFECT GENERATOR

(71) Applicant: HONDA MOTOR CO., LTD., Tokyo (JP)

(72) Inventors: Xun WANG, Wako-shi (JP); Toshio INOUE, Wako-shi (JP)

(21) Appl. No.: 19/044,702

(22) Filed: Feb. 4, 2025

(30) Foreign Application Priority Data
Feb. 8, 2024 (JP) 2024-017713

(51) Int. Cl. G10K 11/02; H03G 3/30; H04R 1/02; H04R 3/04

(52) U.S. Cl. CPC G10K 11/02; H03G 3/301; H04R 1/025; H04R 3/04; H03G 2201/103; H04R 2430/01; H04R 2499/13

(57) ABSTRACT

An active driving sound effect generator is an active driving sound effect generator mounted on a vehicle and includes a waveform generator configured to generate a signal from a waveform table depending on vehicle information, and a speaker configured to output the signal generated by the waveform generator. The waveform table is a cyclic waveform table in which an end point and a start point of the waveform table are continuous and contains multiple frequency components.

### BACKGROUND OF THE INVENTION

### 1. Field of the Invention

The present invention relates to an active driving sound effect generator.

### 2. Description of the Related Art

Heretofore, regarding vehicle driving operations, an active sound effect generator has been studied which generates sound effects according to changes in the vehicle speed in response to driver's accelerator pedal operations (for example, Patent Literature 1 and Patent Literature 2).

Regarding the technique related to an active sound effect generator, Abstract of JA2015-229403A describes an active sound effect generator that can realize at least one of generation of more natural sound effects and applicability of the generator even to an electric vehicle (see Patent Literature 1).

ABSTRACT of Patent Literature 2 describes an active sound effect generator which generates a sound effect along with an increase in the vehicle speed such that the sound effect is highly realistic as an automobile driving sound even in a high-speed region (see Patent Literature 2).

### PRIOR ART DOCUMENT(S)

### Patent Literature(s)

Patent Literature 1: JP2015-229403A
Patent Literature 2: JP2019-128378A

The active sound effect generators described in Patent Literature 1 and Patent Literature 2 involve a large amount of calculation. Accordingly, a load on the processing is high and makes it difficult to provide a driving sound effect in real time.

For example, the active sound effect generator described in Patent Literature 1 includes a reference signal generator and a control signal generator. The reference signal generator generates a reference signal by sequentially reading waveform data from a waveform data table. The control signal generator generates a control signal for use to generate a sound effect based on the generated reference signal. The control signal generator adjusts the amplitude of the control signal by changing the amplitude of the reference signal according to a change in the frequency and the load of a driving source.

The active sound effect generator described in Patent Literature 1 also requires a rotational frequency change calculator that calculates a rotational frequency change, which is a time differential value of the rotational frequency, and an engine load detector that detects the engine load, and accordingly involves a large amount of calculation required to adjust the amplitude of the control signal.

Meanwhile, the active sound effect generator described in Patent Literature 2 includes a waveform data table and an amplitude data table. The waveform data table generates ordered acoustic signals having ordered acoustic frequencies from a sine wave of 1 [Hz]. For example, the number of ordered acoustic frequencies is three. In this case, the waveform data table generates three ordered acoustic signals. Meanwhile, the amplitude data table adjusts the amplitude of each of the three ordered acoustic signals. An adder generates an acoustic signal by combining (adding) the three ordered acoustic signals whose amplitudes are adjusted.

In this way, the active sound effect generator described in Patent Literature 2 also places a load on the processing due to the large amount of calculation required for the ordered acoustic signals. In addition, the amount of calculation required for the ordered acoustic signals is further increased in the case of outputting multiple tones (sets of ordered acoustic signals) simultaneously or controlling the volume and other parameters.

In the case where a user desires to individually adjust the waveform (tone) of a sound effect, it is difficult for an ordinary user to adjust the tone because the settings for the ordered sounds are difficult to understand.

### SUMMARY OF THE INVENTION

The present invention was made in view of the above circumstances, and has an object to provide an active driving sound effect generator that generates highly realistic driving sound effects while achieving a reduction in the amount of calculation in the process of generating sound signals and enabling easy adjustment of a tone.

In order to achieve the above object of the present invention, an active driving sound effect generator is an active driving sound effect generator mounted on a vehicle, comprising: a waveform generator configured to generate a signal from a waveform table depending on vehicle information; and a speaker configured to output the signal generated by the waveform generator, wherein the waveform table is a cyclic waveform table in which an end point and a start point of the waveform table are continuous and contains a plurality of frequency components.

According to the present invention, it is possible to generate highly realistic driving sound effects while achieving a reduction in the amount of calculation in the process of generating sound signals and enabling easy adjustment of a tone.

### BRIEF DESCRIPTION OF THE DRAWINGS

FIG. 1 is a block diagram showing an outline of a configuration of an active driving sound effect generator according to a first embodiment, mounted on a vehicle.

FIG. 2 is a block diagram showing an outline of a configuration of a waveform generator.

FIG. 3A is an explanatory diagram showing a concept in which a generation processor reads a signal (waveform data) at a position specified by a sum of a previous read position and an obtained skip number (No. 1).

FIG. 3B is an explanatory diagram showing the concept in which the generation processor reads the signal (waveform data) at the position specified by the sum of the previous read position and the obtained skip number (No. 2).

FIG. 4 is an explanatory diagram showing an example of processing of synthesizing a waveform table.

FIG. 5 is an explanatory diagram showing characteristics of each gain adjuster of a gain controller to add a gain to a signal obtained from the waveform generator.

FIG. 6 is a block diagram showing a configuration of a sound image control processor.

FIG. 7A shows a display audio provided in a vehicle.

FIG. 7B shows a low frequency waveform table that is an example of a powerful EV sports tone.

FIG. 7C shows a high frequency waveform table that is an example of a futuristic EV tone.

FIG. 8A is an explanatory diagram showing a configuration in which a tone screen of the display audio is provided with a button for adding a tone (waveform table).

FIG. 8B is an explanatory diagram showing a waveform table added to the waveform generator by a user.

FIG. 9A is an explanatory diagram showing a first skip table.

FIG. 9B is an explanatory diagram showing a second skip table.

FIG. 10 is a block diagram showing an outline of a configuration of an active driving sound effect generator according to a second embodiment, mounted on a vehicle.

FIG. 11A shows a coefficient of a band-pass filter included in a frequency characteristic adjustment processor.

FIG. 11B is an explanatory diagram showing frequency characteristics based on the filter coefficient.

FIG. 12A is an explanatory diagram showing signals input to frequency characteristic adjustment processors.

FIG. 12B is an explanatory diagram showing signals output from the frequency characteristic adjustment processors.

FIG. 13 is an explanatory diagram showing a configuration to switch a filter coefficient of the active driving sound effect generator according to the second embodiment.

FIG. 14 is an explanatory diagram showing a comparative example of generating a waveform table containing multiple frequency components.

### DETAILED DESCRIPTION OF THE EMBODIMENTS

Hereinafter, embodiments for carrying out the present invention will be described in detail. The embodiments described below are examples for carrying out the present invention, and should be modified or altered as needed depending on the structure of an apparatus and various conditions to which the present invention is applied. The present invention should not be limited to the embodiments described below. Moreover, in the drawings, the same constituent elements will be denoted with the same reference signs and description thereof will be omitted if unnecessary.

### First Embodiment

### [Outline of Configuration of Active Driving Sound Effect Generator]

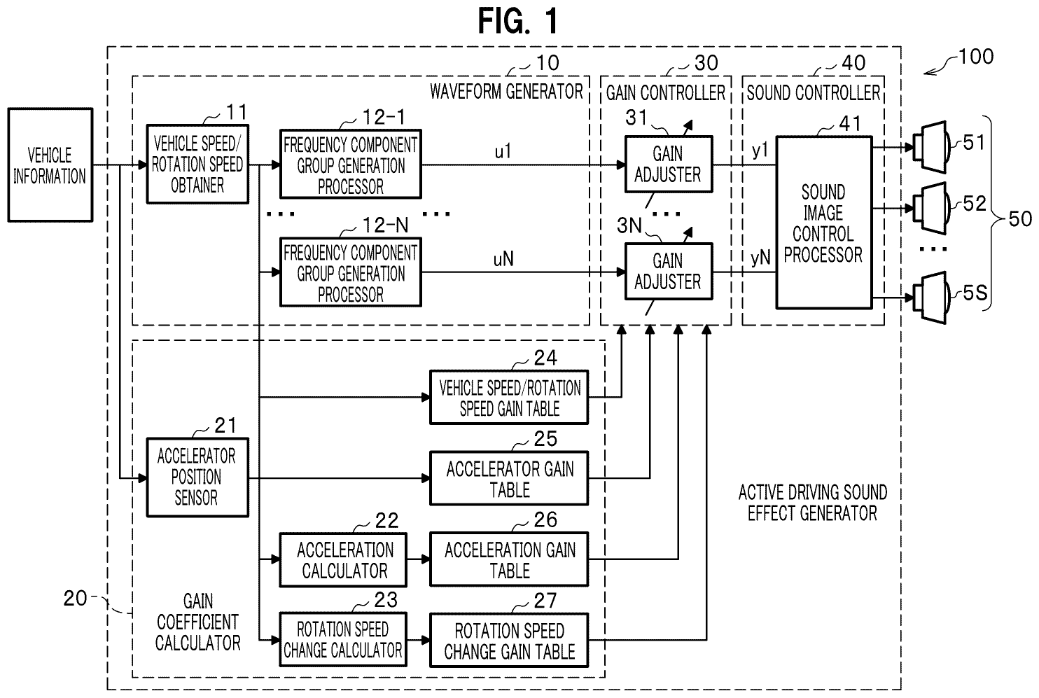

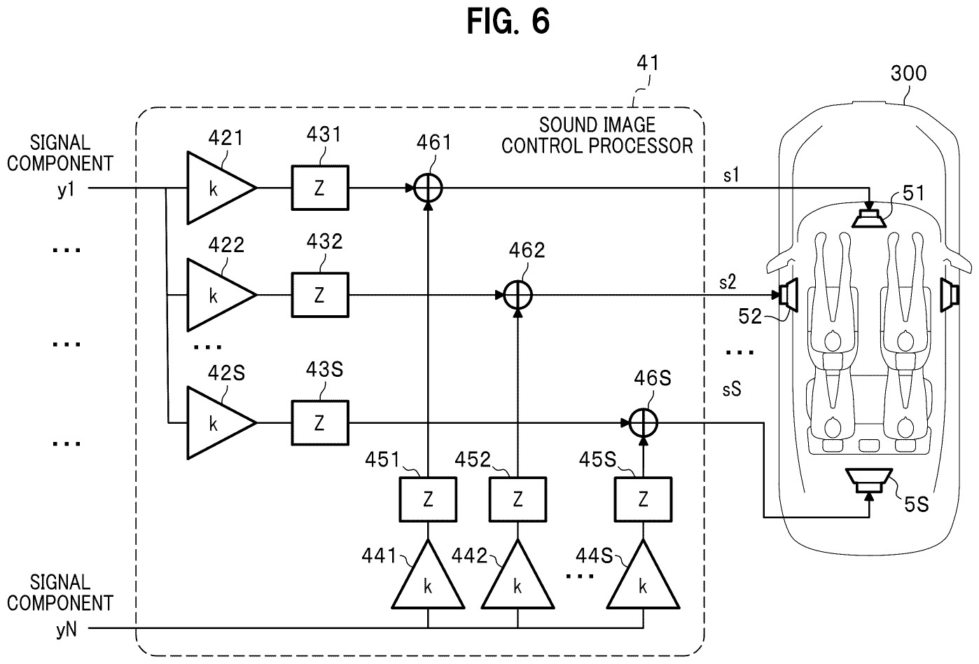

FIG. 1 is a block diagram showing an outline of a configuration of an active driving sound effect generator according to a first embodiment, mounted on a vehicle (see FIG. 6).

As shown in FIG. 1, an active driving sound effect generator 100 according to the present embodiment includes a waveform generator 10, a gain coefficient calculator 20, a gain controller 30, a sound controller 40, and speakers 50.

In the present embodiment, the waveform generator 10, the gain coefficient calculator 20, the gain controller 30, and the sound controller 40 constitute an active sound control (ASC) apparatus. The active sound control is a system for improving the sound quality of an acceleration sound heard inside a vehicle depending on an accelerator position. In other words, the active sound control provides a user with an acceleration sound according to a vehicle speed or a rotation speed of a power unit by outputting the sound synchronized with the vehicle speed or the rotation speed from the speakers 50 to the inside of the vehicle.

As shown in a vehicle 300 in FIG. 6 to be described later, the speakers 50 shown in FIG. 1 include a speaker 51 arranged on a front side of the vehicle 300 (for example, in front of a driver's seat and a front passenger seat), a speaker 52 arranged at approximately the center of the vehicle 300 (for example, beside the driver's seat or the front passenger seat), and a speaker 5S arranged on a rear side of the vehicle 300 (for example, behind rear passenger seats).

The vehicle 300 is any of electric automobiles including, for example, a fuel cell vehicle and a hybrid vehicle, and the like, and includes a motor (not shown). This motor is controlled by a motor electronic controller (ECU) (not shown).

The waveform generator 10 of the active driving sound effect generator 100 generates a signal from a waveform table according to vehicle information. The waveform generator 10 includes multiple waveform tables and generates signals respectively from the multiple waveform tables. The vehicle information herein indicates a vehicle speed or a rotation speed of a power unit. The power unit is not limited to the motor, but may be, for example, an engine.

The waveform generator 10 includes a vehicle speed/rotation speed obtainer 11 and frequency component group generation processors 12-1, . . . , 12-N. The frequency component group generation processors 12-1, . . . , 12-N will be also simply referred to as the frequency component group generation processors 12 when any one of them does not have to be specified.

The vehicle speed/rotation speed obtainer 11 obtains, as the vehicle information, the vehicle speed or the rotation speed of the power unit from the vehicle 300 (see FIG. 6). The vehicle speed/rotation speed obtainer 11 includes, for example, a vehicle speed sensor. The vehicle speed/rotation speed obtainer 11 obtains the vehicle speed or the rotation speed of the power unit based on a rotation speed of the motor or a vehicle shaft (not shown) by means of the vehicle speed sensor, and supplies the obtained information to the gain coefficient calculator 20.

Each of the frequency component group generation processors 12-1, . . . , 12-N has a corresponding waveform table (tone). For example, the frequency component group generation processor 12-1 has a low frequency waveform table containing relatively many low frequency components, while a frequency component group generation processor 12-2 (where N is 2) has a high frequency waveform table containing more high frequency components than the low frequency waveform table does. The low frequency waveform table only has to contain more low frequency components than high frequency components and may be composed of only low frequency components. The high frequency waveform table only has to contain more high frequency components than low frequency components, and may be composed of only high frequency components. The low frequency waveform table and the high frequency waveform table are not limited to waveform tables but may be data containing low frequency waveform signals and high frequency waveform signals.

The waveform generator 10 includes multiple waveform tables because the frequency component group generation processors 12-1, . . . , 12-N include respectively different waveform tables.

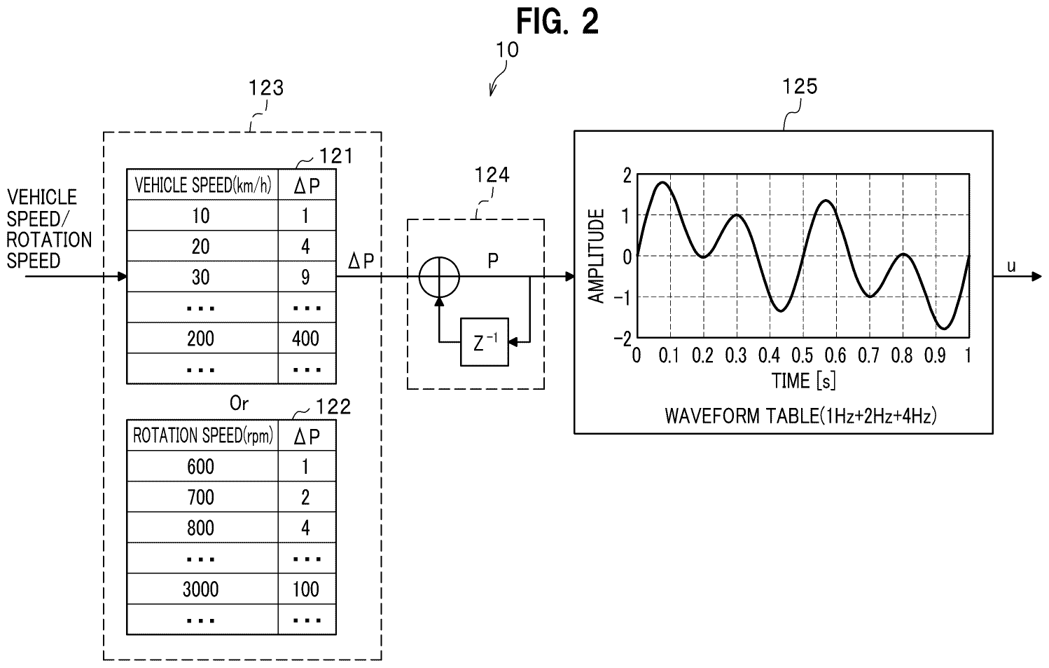

FIG. 2 is a block diagram showing an outline of a configuration of the waveform generator. As shown in FIG. 2, the waveform generator 10 includes a skip table 123 and a generation processor 124. The generation processor 124 has a waveform table 125 that forms a tone. The waveform table 125 contains waveform data to be read by the generation processor 124 and is composed of table values. The waveform table 125 is an example of waveform data which has one cycle of 1 [s] and which contains multiple frequency components (1 [Hz], 2 [Hz], and 4 [Hz]).

The skip table 123 obtains a skip number for read positions based on the vehicle information. The skip table 123 is provided to, for example, the vehicle speed/rotation speed obtainer 11.

The skip table 123 includes at least one of a vehicle speed step table 121 and a rotation speed step table 122. In the vehicle speed step table 121, a skip number (read pitch) ΔP is defined based on the vehicle speed [km/h] of the vehicle 300. In the rotation speed step table 122, a skip number ΔP is defined based on the rotation speed [rpm] of the power unit. The skip number specifies, for example, a read pitch at which waveform data is to be read from the waveform table 125. In other words, the skip number specifies a rate for thinning out the waveform table 125, and is set to an n-times speed value for playback of the waveform table 125 at n-times speed.

The skip table 123 stores skip numbers ΔP in a table format. For example, based on the vehicle speed step table 121, the vehicle speed/rotation speed obtainer 11 reads a skip number ΔP of 1 when the vehicle speed is 10 [km/h] and reads a skip number ΔP of 4 when the vehicle speed is 20 [km/h]. In addition, the vehicle speed/rotation speed obtainer 11 reads a skip number ΔP of 9 when the vehicle speed is 30 [km/h] and reads a skip number ΔP of 400 when the vehicle speed is 200 [km/h].

Meanwhile, for example, based on the rotation speed step table 122, the vehicle speed/rotation speed obtainer 11 reads a skip number ΔP of 1 when the rotation speed of the power unit is 600 [rpm] and reads a skip number ΔP of 2 when the rotation speed of the power unit is 700 [rpm]. The vehicle speed/rotation speed obtainer 11 reads a skip number ΔP of 4 when the rotation speed of the power unit is 800 [rpm] and reads a skip number ΔP of 100 when the rotation speed of the power unit is 3000 [rpm].

In this way, when the vehicle speed/rotation speed obtainer 11 obtains the vehicle speed or the rotation speed of the power unit, the waveform generator 10 obtains the skip number ΔP for the read positions based on the obtained vehicle speed or rotation speed. In the vehicle speed step table 121 or the rotation speed step table 122, skip numbers desired by a user are defined as the skip numbers ΔP.

Meanwhile, the generation processor 124 is provided to each of the frequency component group generation processors 12-1, . . . , 12-N. In other words, the generation processors 124 correspond to the respective frequency component group generation processors 12-1, . . . , 12-N. Based on the skip number ΔP obtained by the vehicle speed/rotation speed obtainer 11, each of the generation processors 124 reads the signal in the waveform table 125 at every position specified by the sum of every previous read position and the obtained skip number ΔP, thereby generating a signal (that is, a waveform table read at intervales of the skip number ΔP) to be input to the speakers 50.

Here, the signal generated by the generation processor 124 is defined by following Formula (1):

$$\begin{matrix}[ Formula 1 ] & \\ P ( t + 1 ) = P ( t ) + Δ P ( t ) , & ( 1 )\end{matrix}$$

where P(t) denotes a pointer, P(0) denotes an initial value 0, and ΔP(t) denotes a skip number.

As shown in Formula (1), the signal to be input to the speakers 50 is generated, based on the skip number ΔP read from the skip table 123 by the vehicle speed/rotation speed obtainer 11 and the previous value of the pointer P(t), by reading out the waveform table 125 at the position advanced by the skip number ΔP from the previous value of the pointer (t). In this case, the waveform data pieces in the waveform table 125 read at the intervals of the skip number ΔP constitute the signal (tone).

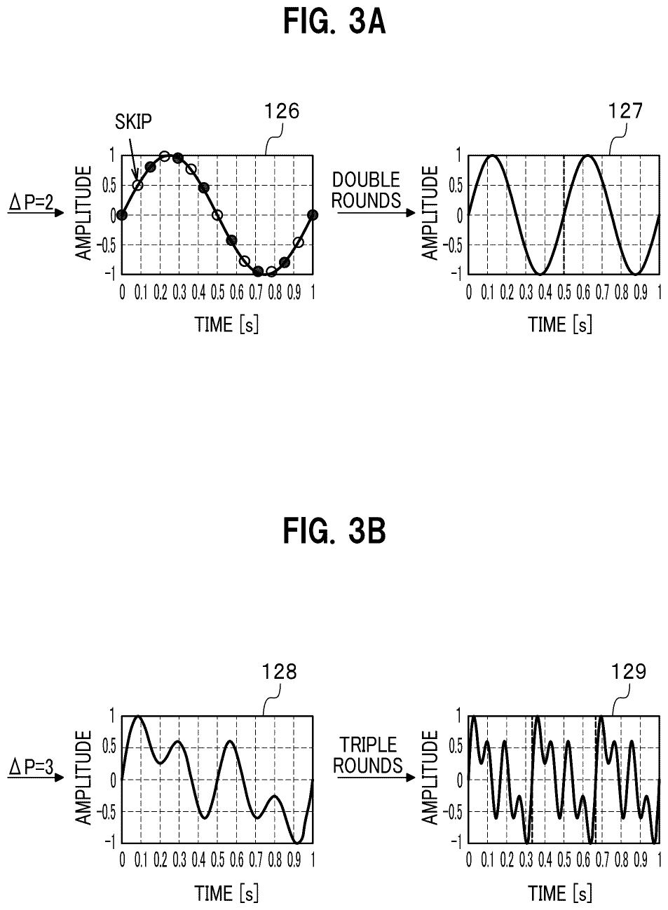

FIGS. 3A and 3B are explanatory diagrams showing a concept in which the generation processor reads a signal (waveform data) at every position specified by the sum of every previous read position and the obtained skip number ΔP.

FIG. 3A shows a concept in which the generation processor 124 reads a signal (waveform data) from a waveform table 126, for example, when the skip number ΔP is 2. As shown in FIG. 3A, from waveform data (the waveform table 126) with one cycle per second, the generation processor 124 reads waveform data (waveform table 127) in double cycles (double rounds) from the previous read position.

FIG. 3B shows a concept in which the generation processor 124 reads a signal (waveform data) from a waveform table 128, for example, when the skip number ΔP is 3. As shown in FIG. 3B, from waveform data (waveform table 128) with one cycle per second, the generation processor 124 reads waveform data (waveform table 129) in triple cycles (triple rounds) from the previous read position.

Here, each of the waveform tables 126 and 128 holds one cycle of values of the signal (waveform data) in a table data format. The present embodiment has a feature in the waveform tables 126 and 128 from which the waveform generator 10 reads the waveform data.

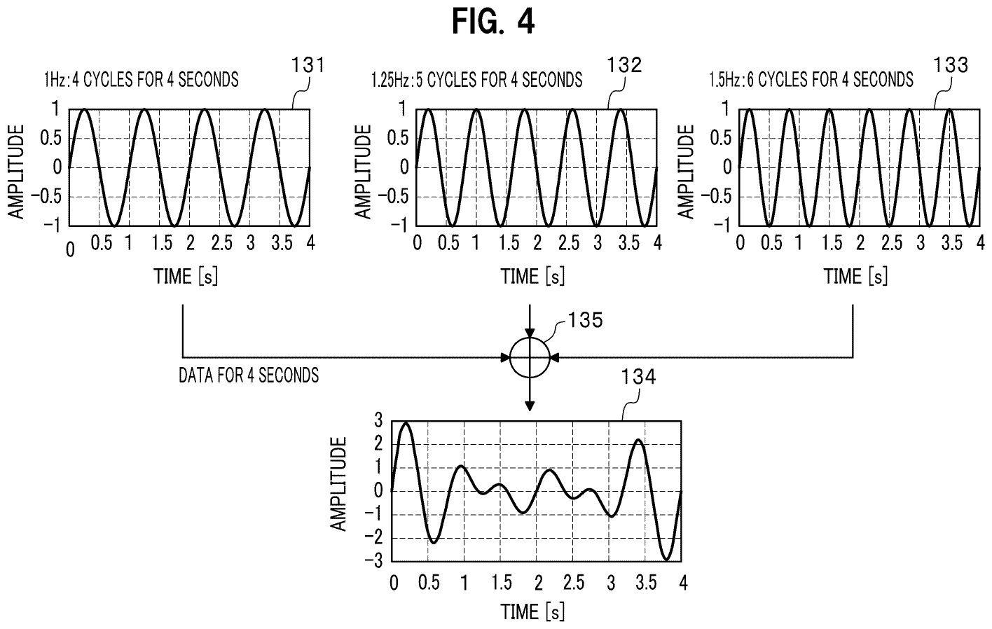

FIG. 4 is an explanatory diagram showing an example of processing for synthesizing a waveform table. FIG. 4 shows the processing for synthesizing a waveform table 134 of waveform data having three frequency components from a waveform table 131 with a frequency of 1 [Hz], a waveform table 132 with a frequency of 1.25 [Hz], and a waveform table 133 with a frequency of 1.5 [Hz].

The three waveform tables 131, 132, and 133 have different cycles, and therefore cannot be synchronized in the unit of one second. For this reason, in the present embodiment, in order to generate the waveform table 134 having the three frequency components, the frequencies of the waveform tables 131, 132, and 133 are multiplied by every integer value while their frequency ratio is maintained, and a minimum time [s](multiplier) at which the three waveform tables 131, 132, and 133 can be synchronized is determined among the integer values with each of which all the integer multiples of the frequencies are converted to integers. As a result of transforming the waveform data in the waveform tables 131, 132, and 133 to waveform data whose frequency ratio is expressed by the integers, the waveform data in the waveform tables 131, 132, and 133 take the same values at the start point and the end point of the minimum time [s] and can be synchronized at every timing therein. Thus, in the present embodiment, one cycle is set to the minimum time [s] at which the waveform tables 131, 132, and 133 can be synchronized, and the waveform table 134 having the three frequency components is synthesized by combining the waveform data in all the waveform tables 131, 132, and 133.

In this way, in the present embodiment, after the numeric values in the frequency ratio of the waveform tables 131, 132, and 133 are converted to integers, a time (minimum time) for minimum required data strings of waveform data is determined.

In the case in FIG. 4, the frequency ratio of the waveform table 131 with 1 [Hz], the waveform table 132 with 1.25 [Hz], and the waveform table 133 with 1.5 [Hz] is 1:1.25:1.5. This frequency ratio will be 4:5:6 or 100:125:150 as a result of multiplication by an integer. In this case, the minimum time [s] at which the waveform tables 131, 132, and 133 can be synchronized is determined as 4 [s] because (1:1.25:1.5)×4 is equal to 4:5:6. With the determination of the minimum time (4 [s]), the waveform data in the waveform table 131 is transformed to waveform data for four cycles, the waveform data in the waveform table 132 is transformed to waveform data for five cycles, and the waveform data in the waveform table 133 is transformed to waveform data for six cycles.

Then, for the waveform table 134, the waveform data for the minimum time [s] set as one cycle is generated by adding up the cyclic data of the integer multiples (four cycles, five cycles, and six cycles) of the waveform tables 131, 132, and 133 within the minimum time (4 [s]) at which the waveform tables 131, 132, and 133 can be synchronized. Thus, the generated waveform table 134 is a cyclic waveform table in which the end point and the start point of the waveform data are continuous, and is the table containing the multiple frequency components.

In other words, in the present embodiment, the waveform table 134 is formed of the waveform data with one cycle of the waveform table set to a minimum multiplier (that is, a minimum time) with which all the numeric values in the ratio of the multiple frequencies are converted to integers while their frequency ratio is maintained.

In this way, the waveform table 134 containing the multiple frequency components is generated from the waveform data in the waveform tables 131, 132, and 133 containing the frequency components desired by a user.

Returning to FIG. 1, the gain coefficient calculator 20 in the active driving sound effect generator 100 includes an accelerator position sensor 21, an acceleration calculator 22, a rotation speed change calculator 23, a vehicle speed/rotation speed gain table 24, an accelerator gain table 25, an acceleration gain table 26, and a rotation speed change gain table 27.

The accelerator position sensor 21 detects the position of an accelerator pedal (this will be referred to as the accelerator position θ) when the user depresses the accelerator pedal of the vehicle 300.

The acceleration calculator 22 obtains the vehicle speed or the rotation speed of the power unit from the vehicle speed/rotation speed obtainer 11 and calculates an acceleration Δa.

The rotation speed change calculator 23 obtains the vehicle speed or the rotation speed of the power unit from the vehicle speed/rotation speed obtainer 11 and calculates a rotation speed change Δb.

The vehicle speed/rotation speed gain table 24 has a feature of adding a gain to the vehicle speed or the rotation speed of the power unit provided. The accelerator gain table 25 has a feature of adding a gain to the detected accelerator position θ. The acceleration gain table 26 has a feature of adding a gain to the calculated acceleration Δa. The rotation speed change gain table 27 has a feature of adding a gain to the calculated rotation speed change Δb.

In each of the vehicle speed/rotation speed gain table 24, the accelerator gain table 25, the acceleration gain table 26, and the rotation speed change gain table 27, certain characteristics desired by the user are set as needed in a table format.

The gain controller 30 of the active driving sound effect generator 100 includes multiple gain adjusters 31, . . . , 3N. The gain controller 30 obtains signals u1, . . . , uN generated in the respective frequency component group generation processors 12-1, . . . , 12-N and obtains a coefficient for adjusting the gain of each of the signals u1, . . . , uN from the gain coefficient calculator 20.

The multiple gain adjusters 31, . . . , 3N are in charge of the respective signals u1, . . . , uN generated from the waveform tables in the frequency component group generation processors 12-1, . . . , 12-N. Thus, each of the gain adjusters 31, . . . , 3N adjusts the gain of the corresponding one of the signals u1, . . . , uN generated in the frequency component group generation processors 12-1, . . . , 12-N by using the coefficient of the gain obtained from the gain coefficient calculator 20.

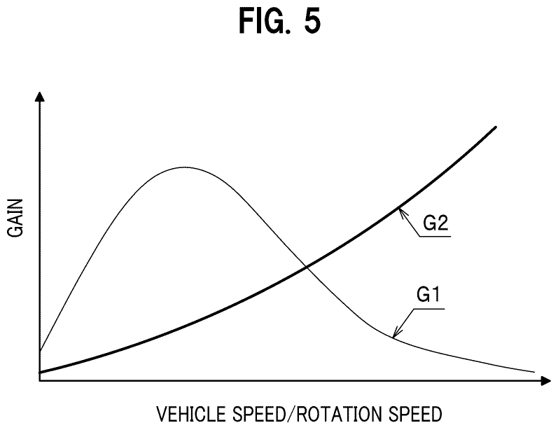

FIG. 5 is an explanatory diagram showing characteristics of each of the gain adjusters of the gain controller to add a gain to a signal obtained from the waveform generator.

As shown in FIG. 5, when the vehicle speed or the rotation speed is relatively low, the gain controller 30 increases (raises) a gain for the low frequency waveform table according to a gain G1 prescribed for low frequency components. On the other hand, when the vehicle speed or the rotation speed is relatively high, the gain controller 30 increases a gain for the high frequency waveform table according to a gain G2 prescribe for high frequency components.

In FIG. 5, the gain G1 shows characteristics of the gain for the low frequency components (low frequency waveform signals) and the gain G2 shows characteristics of the gain for the high frequency components (high frequency waveform signals).

For example, in the case where the frequency component group generation processor 12-1 includes a low frequency waveform table and the frequency component group generation processor 12-2 (where N is 2) includes a high frequency waveform table, the gain adjuster 31 emphasizes and outputs the low frequency components in the low frequency waveform table of the frequency component group generation processor 12-1 according to the gain G1, when the vehicle speed or the rotation speed is relatively low.

On the other hand, when the vehicle speed or the rotation speed is relatively high, the gain adjuster 32 (where N is 2) emphasizes and outputs the high frequency components in the high frequency waveform table of the frequency component group generation processor 12-2 according to the gain G2.

The sound controller 40 (see FIG. 1) of the active driving sound effect generator 100 includes a sound image control processor 41. The sound image control processor 41 changes (adjusts) the volume of an output of each of multiple signal components y1, . . . , yN from each of the multiple speakers 50 (51, 52, . . . , 5S).

The sound image control processor 41 inputs the signals to each of the speakers 50 and each of the speakers 50 outputs an output sound, which is expressed by following Formula (2):

$$\begin{matrix}[ Formula 2 ] & \\ {s}_{S} = {\sum }_{n = 1}^{N} {Z}^{- {D}_{nS}} {k}_{nS} {y}_{n} , & ( 2 )\end{matrix}$$

where S_{S} denotes an output sound of an S-th speaker, n denotes a frequency component number, N denotes a total number of frequency component groups, K_{nS} denotes a gain coefficient for outputting an n-th frequency component group from the S-th speaker, and D_{nS} denotes a time delay for outputting the n-th frequency component group from the S-th speaker.

As shown in Formula (2), for each of the signal components y1, . . . , yN obtained from the signals u1, . . . , uN generated in the frequency component group generation processors 12-1, . . . , 12-N, the sound image control processor 41 adjusts the volume by multiplying the signal component by each of gains set for the respective speakers 50, and also adjusts the delay time. As a result, the output sound from each of the speakers 51, 52, . . . , 5S is a sum total (result) of the frequency components with the adjusted volumes.

As a result, the sound image control processor 41 outputs the low frequency waveform signals (low frequency components) at relatively low volumes and outputs the high frequency waveform signals (high frequency components) at relatively high volumes from the speaker 51 arranged on the front side of the vehicle 300, and outputs the low frequency waveform signals (low frequency components) at higher volumes and outputs the high frequency waveform signals (high frequency components) at lower volumes from the speaker 5S arranged on the rear side than from the speakers 51 and 52 arranged on the front side.

In addition, the sound image control processor 41 is capable of adjusting a signal phase of each of the multiple signal components y1, . . . , yN for each of the speakers 50. Thus, the speaker 51 arranged on the front side of the vehicle 300 is enabled to output the high frequency waveform signals earlier and the low frequency waveform signals later than the speaker 5S arranged on the rear side of the vehicle 300 does.

FIG. 6 is a block diagram showing a configuration of the sound image control processor. As shown in FIG. 6, the sound image control processor 41 includes amplifiers 421, 422, . . . , 42S, 441, 442, . . . , 44S each of which multiplies the corresponding one of the multiple signal components y1, . . . , yN by a constant for the corresponding one of the speakers 51, 52, . . . , 5S.

FIG. 6 shows the case where the speakers 51, 52, . . . , 5S are arranged. In this case, for the signal component y1 of the frequency component group generation processor 12-1, which assumes an intake sound, the sound image control processor 41 sets, for example, a coefficient of 1.0 for the amplifier 421, a coefficient of 0.5 for the amplifier 422, and a coefficient of 0.0 for the amplifier 42S. As a result, the sound image control processor 41 localizes a sound image of the signal component y1 on the front side of the vehicle.

On the other hand, for the signal component yN of the frequency component group generation processor 12-N, which assumes an exhaust sound, the sound image control processor 41 sets, for example, a coefficient of 0.0 for the amplifier 441, a coefficient of 0.5 for the amplifier 442, and a coefficient of 1.0 for the amplifier 44S. As a result, the sound image control processor 41 localizes a sound image of the signal component yN on the rear side of the vehicle.

As a result, the speaker 51 outputs the high frequency components at higher volumes than the speakers 52 and 5S do, and the speaker 52 outputs the high frequency components at higher volumes than the speaker 5S does. On the other hand, the speaker 5S outputs the low frequency components at higher volumes than the speakers 51 and 52 do, and the speaker 52 outputs the low frequency components at higher volumes than the speaker 51 does. The sound image control processor 41 may divide the multiple speakers 50 (51, 52, . . . , 5S) into front and rear groups in a vehicle cabin, and collectively control the speakers in each of the groups.

The sound image control processor 41 also includes delay adjustment elements 431, 432, . . . , 43S, 451, 452, . . . , 45S each of which adjusts the signal phase of the corresponding one of the multiple signal components y1, . . . , yN for the corresponding one of the speakers 51, 52, . . . , 5S.

In the delay adjustment elements 431, 432, . . . , 43S, 451, 452, . . . , 45S, a digital value is set as a delay time for each of the signal components y1, . . . , yN. This makes it possible for the speaker 51 arranged on the front side of the vehicle 300 to output the high frequency waveform signals (high frequency components) earlier and output the low frequency waveform signals (low frequency components) later than the speakers 52, . . . , 5S arranged on the rear side of the vehicle 300 do.

Thus, the speaker 51 outputs an added signal s1 into the vehicle cabin, the added signal s1 obtained by an adder 461 adding the signal amplified by the amplifier 421 and delayed by the delay adjustment element 431 and the signal amplified by the amplifier 441 and delayed by the delay adjustment element 451. The speaker 52 outputs an added signal s2 into the vehicle cabin, the added signal s2 obtained by an adder 462 adding the signal amplified by the amplifier 422 and delayed by the delay adjustment element 432 and the signal amplified by the amplifier 442 and delayed by the delay adjustment element 452. The speaker 5S outputs an added signal sS into the vehicle cabin, the added signal sS obtained by an adder 46S adding the signal amplified by the amplifier 42S and delayed by the delay adjustment element 43S and the signal amplified by the amplifier 44S and delayed by the delay adjustment element 45S.

### [Operations of Active Driving Sound Effect Generator]

### <Operation 1>

Next, operations of the active driving sound effect generator 100 according to the first embodiment will be described in reference to FIG. 1 and FIGS. 7A to 9B.

In the active driving sound effect generator 100, the vehicle speed/rotation speed obtainer 11 obtains the vehicle speed or the rotation speed of the power unit as the vehicle information of the vehicle 300. The vehicle speed/rotation speed obtainer 11 obtains the skip number ΔP based on the obtained vehicle speed or rotation speed of the power unit.

Each of the frequency component group generation processors 12-1, . . . , 12-N (generation processors 124) reads, from the corresponding one of the waveform tables, the signal at the position specified by the sum of the read position P(t) and the skip number ΔP and inputs the read signal to the gain controller 30.

The gain coefficient calculator 20 calculates the gain coefficient for each of the signals u1, . . . , uN based on the accelerator position θ of the accelerator position sensor 21 and the vehicle speed or the rotation speed of the power unit obtained by the vehicle speed/rotation speed obtainer 11, from the vehicle speed/rotation speed gain table 24, the accelerator gain table 25, the acceleration gain table 26, and the acceleration gain table 26.

The gain controller 30 controls (adjusts) the gains for the signals u1, . . . , uN generated from the respective multiple waveform tables in the frequency component group generation processors 12-1, . . . , 12-N, by using the respective gain coefficients calculated by the gain coefficient calculator 20.

The sound controller 40 changes the output volumes for the signal components y1, . . . , yN for each of the multiple speakers 50 and inputs the resultant signal to each of the speakers 50. As a result, each of the speakers 50 can output the signals u1, . . . , uN generated in the waveform generator 10.

### <Operation 2>

In the present embodiment, the active driving sound effect generator 100 includes the multiple waveform tables because the frequency component group generation processors 12-1, . . . , 12-N in the waveform generator 10 include their respective waveform tables. Therefore, the waveform generator 10 can receive a user's operation and switch the waveform table among from the multiple waveform tables according to the user's operation.

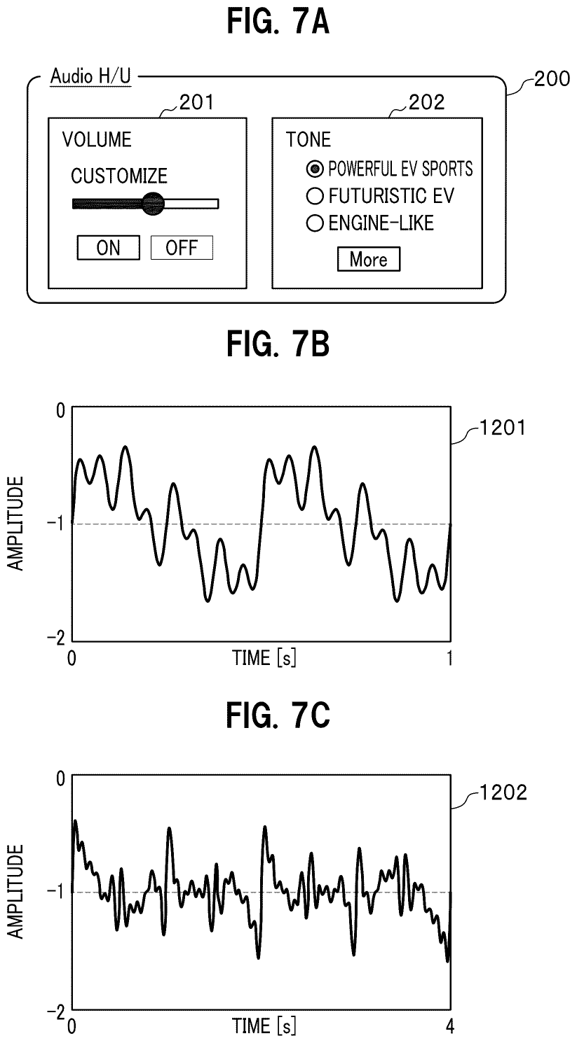

FIGS. 7A to 7C are explanatory diagrams showing that a desired waveform table is selectable from the multiple waveform tables included in the frequency component group generation processors of the waveform generator.

FIG. 7A shows a display audio provided in the vehicle 300. As shown in FIG. 7A, a display audio 200 is provided with a volume screen 201 and a tone screen 202.

The volume screen 201 is configured to receive ON/OFF for customizing a volume adjustment by a user, and allow the user to adjust the volume when ON is set.

The tone screen 202 is configured to enable tone switchover in response to a user's operation of selecting any of buttons. For example, the tone screen 202 allows a selection from a powerful electric vehicle (EV) sports tone and a futuristic EV tone. In this case, when the user selects the powerful EV sports tone, a waveform table 1201 shown in FIG. 7B is selected from the frequency component group generation processors 12-1, . . . , 12-N of the waveform generator 10. On the other hand, when the user selects the futuristic EV tone, a waveform table 1202 shown in FIG. 7C is selected from the frequency component group generation processors 12-1, . . . , 12-N of the waveform generator 10.

The waveform table 1201 in FIG. 7B shows a low frequency waveform table that is an example of the powerful EV sports tone, for example, and the waveform table 1202 in FIG. 7C shows a high frequency waveform table that is an example of the futuristic EV tone, for example.

The waveform table 1201 is provided for, for example, the frequency component group generation processor 12-1, and the waveform table 1202 is provided for, for example, the frequency component group generation processor 12-2, so that the user is allowed to select the waveform table for outputting their favorite tone.

In another possible mode, an extra waveform table for outputting a favorite tone may be added by the user. For example, the tone screen 202 may be configured to include a button 203 for receiving an addition of a tone by the user.

### <Operation 3>

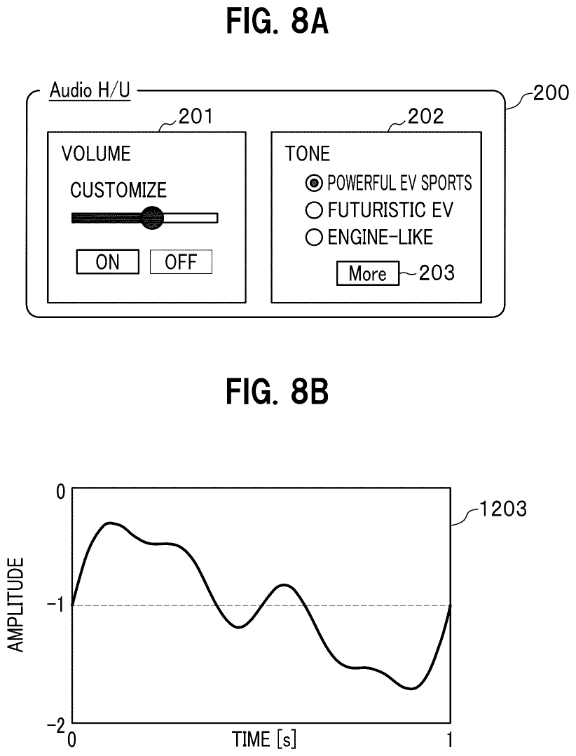

FIG. 8A is an explanatory diagram showing a configuration in which the tone screen of the display audio is provided with a button for adding a tone (waveform table). FIG. 8B is an explanatory diagram showing a waveform table added to the waveform generator by the user. A waveform table 1203 is waveform data downloaded from the Internet as tone data by the user. As similar to the waveform table 134, the waveform table 1203 is a cyclic waveform table in which the end point and the start point of the waveform table are continuous and contains multiple frequency components.

In FIG. 8A, the user is allowed to add a desired waveform table to the waveform generator 10 by pressing down a button 203. Thus, the waveform generator 10 can add the waveform table 1203 to the multiple waveform tables (the frequency component group generation processors 12-1, . . . , 12-N).

The waveform generator 10 is able to switch the waveform table for generating the signals to be input to the speakers 50 to the added waveform table 1203 among the multiple waveform tables. In this case, the user is allowed to add the waveform table 1203 from, for example, the Internet or an external memory, and select an output of the signals of the added waveform table 1203.

In this way, the waveform generator 10 is able to receive addition of the waveform table 1203 and receive a selection of the waveform data (tone) of the waveform table 1203 to be output from the speakers 50.

### <Operation 4>

The waveform generator 10 includes the vehicle speed/rotation speed obtainer 11, and the vehicle speed/rotation speed obtainer 11 includes the skip table 123.

The skip table 123 may include, for example, the vehicle speed step table 121 and the rotation speed step table 122, or may include multiple step tables in short. Thus, in response to a user's selection operation, the skip table 123 can be switched to the selected one of the vehicle speed step table 121 and the rotation speed step table 122.

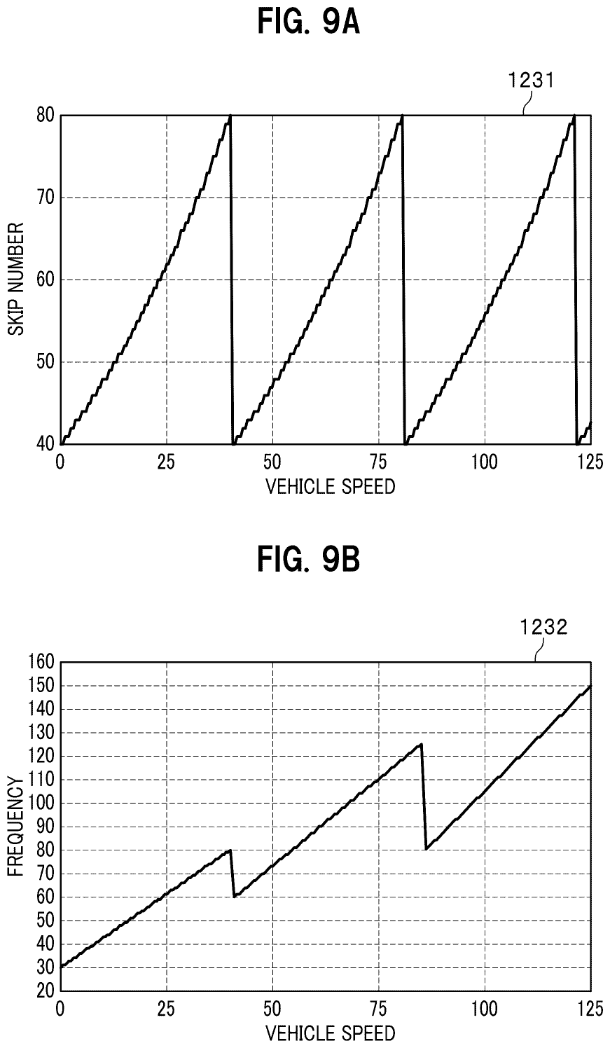

FIG. 9A is an explanatory diagram showing a first skip table 1231. As shown in FIG. 9A, in the first skip table 1231, based on an increase in the vehicle speed or the rotation speed of the power unit, the skip number is exponentially increased from a lower limit value to an upper limit value and is returned to the lower limit value when reaching the upper limit value. In the first skip table 1231, the skip number again is exponentially increased after being returned to the lower limit value. Thus, the first skip table 1231 enables generation of Shepard tone signals.

FIG. 9B is an explanatory diagram showing a second skip table 1232. As shown in FIG. 9B, in the second skip table 1232, a frequency is increased in proportion to an increase in the vehicle speed or the rotational speed of the power unit, and is decreased by a predetermined level when the vehicle speed or the rotational speed reaches a predetermined value. In the second skip table 1232, after the frequency is decreased, the frequency is increased again in proportion to an increase in the vehicle speed or the rotational speed of the power unit, so that the frequency is increased in a stepped manner. Thus, the second skip table 1232 enables generation of engine-like tone signals.

For example, when the futuristic EV tone is selected by a user's selection operation on the tone screen 202 in FIG. 7A or 8A, the first skip table 1231 in FIG. 9A is selected. On the other hand, when an engine-like tone is selected by a user's selection operation on the tone screen 202, the second skip table 1232 in FIG. 9B is selected.

Thus, when the first skip table 1231 is selected, the waveform generator 10 can generate futuristic EV tone signals (Shepard tone signals) in the vehicle speed/rotation speed obtainer 11. On the other hand, when the second skip table 1232 is selected, the waveform generator 10 can generate engine-like tone signals in the vehicle speed/rotation speed obtainer 11.

Here, considered is the case where the first skip table 1231 (Shepard tone signal) is selected, in particular. In this case, even though an engine-like tone can be output, the waveform generator 10 purposely does not control the low frequency waveform signals and the high frequency waveform signals according to the positions of the speakers 50 but outputs them as they are from the speakers 51, 52, . . . , 5S, so that the Shepard tone signals can be output.

As described above, the active driving sound effect generator 100 according to the first embodiment includes the waveform generator 10 and the speakers 50. The waveform generator 10 generates the signals u1 . . . uN from the waveform tables 125, 134 . . . according to the vehicle information. The speakers 50 output the signals u1, . . . , uN generated by the waveform generator 10. Each of the waveform tables 125, 134 . . . is the cyclic waveform table in which the end point and the start point of the waveform table are continuous, and contains the multiple frequency components.

With this configuration, each of the waveform tables 125, 134, . . . included in the waveform generator 10 contains multiple frequency components. For this reason, the amount of calculation can be reduced as compared with a case of combining (superposing) ordered acoustic signals obtained by generating multiple frequency components from a waveform table containing a single frequency component (for example, a sinusoidal wave) as in the related art (for example, such as Patent Literature 1 and Patent Literature 2).

In sum, the active driving sound effect generator 100 according to the first embodiment is able to generate the signals u1 . . . uN to be output from the speakers 50 only by reading the waveform data of the waveform tables 125, 134, . . . , which are the cyclic waveform tables. As a result, the active driving sound effect generator 100 is able to generate a sound signal without needing to perform calculation, which otherwise would impose a load on the processing.

In particular, as described in reference to FIG. 4, the waveform generator 10 includes the waveform table 134 of the waveform data having three (multiple) frequency components. This waveform table 134 is the cyclic waveform table in which the end point and the start point of the waveform data are continuous, and is the table containing the three (multiple) frequency components.

The waveform table 134 contains waveform data formed by adding up the integer multiples of the cyclic data of the waveform tables 131, 132, and 133 for the minimum time (4 [s]) for which the waveform tables 131, 132, and 133 can be synchronized, so that the waveform data has no discontinuity.

### Comparative Example

Here, a comparative example will be described.

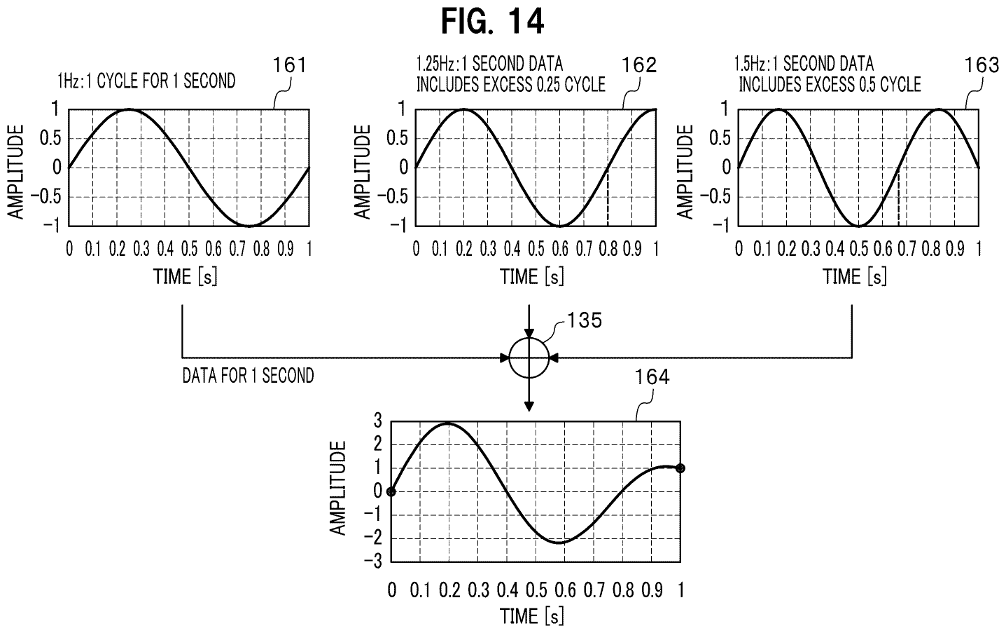

FIG. 14 is an explanatory diagram showing a comparative example of synthesizing a waveform table containing multiple frequency components. FIG. 14 shows processing for synthesizing a waveform table 164 of waveform data having three frequency components from a waveform table 161 with a frequency of 1 [Hz], a waveform table 162 with a frequency of 1.25 [Hz], and a waveform table 163 with a frequency of 1.5 [Hz].

Since the three waveform tables 161, 162, and 163 have different cycles, the non-cyclic waveform table 164 is generated when waveform data pieces for 1 [s] in these waveform tables 161, 162, and 163, as they are, are added up by an adder 135.

In particular, the waveform table 164 is formed of the sum of the waveform data pieces for 1 [s] in the respective waveform tables 161, 162, and 163. In this case, regarding the waveform tables 162 and 163, only some of the waveform data pieces per cycle are added, so that the waveform table 164 lacks the full waveform data pieces per cycle in the waveform tables 161, 162, and 163. Specifically, in the waveform table 164, the start point of the waveform data for 1 [s] takes 0 but the end point thereof takes 1, so that the start point and the end point are discontinuous. In this case, when the waveform data of the waveform table 164 is repeatedly read, discontinuity occurs due to the discontinuous start point and end point. As a result, if the waveform table 164 is applied to a cyclic waveform table to be continuously repeated, the active driving sound effect generator 100 will make a sound gap between the start point and the end point.

In the related art, to avoid a sound gap due to discontinuity in a waveform table, multiple waveform tables each containing a single frequency component are prepared, specific kinds of operations are performed by using these waveform tables, and then the resultant waveform tables are combined by an adder.

In contrast to this, in the waveform table 134 in the first embodiment, the numeric values in the frequency ratio of the waveform tables 131, 132, and 133 are first converted to integers, and then the time (minimum time) for minimum required data strings of the waveform data is determined as one cycle. In other words, in the waveform table 134, desired waveform data is generated by adding up the integer multiples of the cyclic data (waveform data) of the waveform tables 131, 132, and 133 under the setting in which the minimum time [s] for which the waveform tables 131, 132, and 133 can be synchronized is set as one cycle. Even when the waveform data is read repeatedly, this ensures a sound continuity without causing a sound gap at a middle point in any of the cycles. Since the waveform table 134 can be generated by combining waveform tables containing desired frequency components, the tone can be easily adjusted to a tone desired by the user.

Thus, the active driving sound effect generator 100 according to the first embodiment enables easy adjustment of a tone, and accordingly enables generation of a highly-realistic driving sound effect.

The waveform generator 10 includes the multiple waveform tables and generates the signals u1, . . . , uN respectively from the multiple waveform tables. The active driving sound effect generator 100 includes the multiple gain adjusters 31, . . . , 3N respectively corresponding to the signals u1, . . . , uN generated from the multiple waveform tables by the waveform generator 10.

With this configuration, the frequency component group generation processors 12-1, . . . , 12-N include their respective waveform tables, and the active driving sound effect generator 100 includes the gain adjusters 31, . . . , 3N respectively corresponding to the frequency component group generation processors 12-1, . . . , 12-N.

Thus, the active driving sound effect generator 100 is able to adjust the gains for the generated signals u1, . . . , uN and superimpose the gain-adjusted signals u1, . . . , uN, thereby composing a chord and generating a desired complex tone.

Moreover, the waveform generator 10 includes the waveform table 1201 (low frequency waveform table) containing relatively many low frequency components and the waveform table 1202 (high frequency waveform table) containing more high frequency components than the waveform table 1201 does. The vehicle information indicates the vehicle speed or the rotation speed of the power unit. When the vehicle speed or the rotation speed is relatively low, the gain for the waveform table 1201 is increased. On the other hand, when the vehicle speed or the rotation speed is relatively high, the gain for the waveform table 1202 is increased.

With this configuration, as shown in FIG. 5, in a low vehicle speed range, the waveform generator 10 can generate strongly powerful signals like an engine sound by setting a high gain for the low frequency components in the waveform table 1201 according to the gain G1 and setting a low gain for the high frequency components in the waveform table 1202 according to the gain G2. In this way, the waveform generator 10 can generate a tone that will give an acceleration sensation.

As the vehicle 300 accelerates, the waveform generator 10 can generate signals of a frisky exhaust sound by setting a high gain for the high frequency components in the waveform table 1202 according to the gain G2 and setting a low gain for the low frequency components in the waveform table 1201 according to the gain G1 in a high vehicle speed range. In this way, the waveform generator 10 can generate an invigorating tone.

Moreover, in the operation 2 as described in reference to FIGS. 7A to 7C, the waveform generator 10 includes the multiple waveform tables 1201 and 1202 and is able to switch between the multiple waveform tables 1201 and 1202 in response to a user's operation.

With this configuration, the waveform generator 10 can switch between the powerful EV sports tone and the futuristic EV tone in response to a user's selection made on the tone screen 202 of the display audio 200, thereby providing a passenger in the vehicle 300 with a more preferred sound.

Furthermore, in the operation 3 as described in reference to FIGS. 8A and 8B, the waveform generator 10 can further include the waveform table 1203 added by a user's operation, and is able to switch the waveform table for generating the signals u1, . . . , uN to the added waveform table 1203 among the multiple waveform tables.

With this configuration, in the waveform generator 10, extra waveform data of a tone desired by a user may be added later in addition to default waveform data equipped in the active driving sound effect generator 100, so that the active driving sound effect generator 100 can provide a sound effect more suited for user's preference.

In addition, as described in reference to FIG. 2, the waveform generator 10 may include the skip table 123 and the generation processors 124. The skip table 123 obtains the skip number ΔP for the read positions based on the vehicle information. Each of the generation processors 124 reads the signal in the waveform table at every position specified by the sum of each previous read position and the obtained skip number ΔP, and generates the corresponding one of the signals u1, . . . , uN to be input to the speakers 50.

With this configuration, the waveform generator 10 only has to read the skip number ΔP from the skip table 123 according to a driving condition of the vehicle 300, and add the skip number ΔP to the previous read position, so that the amount of calculation can be further reduced.

As shown in FIGS. 9A and 9B, the skip table 123 may include multiple skip tables such as the first skip table 1231 and the second skip table 1232 and can be switched therebetween in response to a user's selection operation.

With this configuration, the waveform generator 10 can switch the frequency by using the skip number ΔP according to the driving condition of the vehicle 300 based on the vehicle speed or the rotation speed of the power unit, thereby making it possible to provide a sound effect even more suited for user's preference. In particular, since a desired tone can be provided simply by switching the waveform data (data values in the table formats) to the first skip table 1231, the second skip table 1232, or the like, there is no need to change a software's calculation formula, and the skip table 123 can be easily switched to the desired one.

Moreover, the vehicle information indicates the vehicle speed or the rotation speed of the power unit, and the first skip table 1231 in FIG. 9A may be set such that, based on an increase in the vehicle speed or the rotation speed of the power unit, the skip number is exponentially increased from the lower limit value to the upper limit value and is returned to the lower limit value when reaching the upper limit value.

With this configuration, the first skip table 1231 in FIG. 9A enables generation of Shepard tone signals. Thus, the waveform generator 10 is able to easily generate a Shepard tone by using the first skip table 1231 in FIG. 9A.

### Second Embodiment

### [Outline of Configuration of Active Driving Sound Effect Generator]

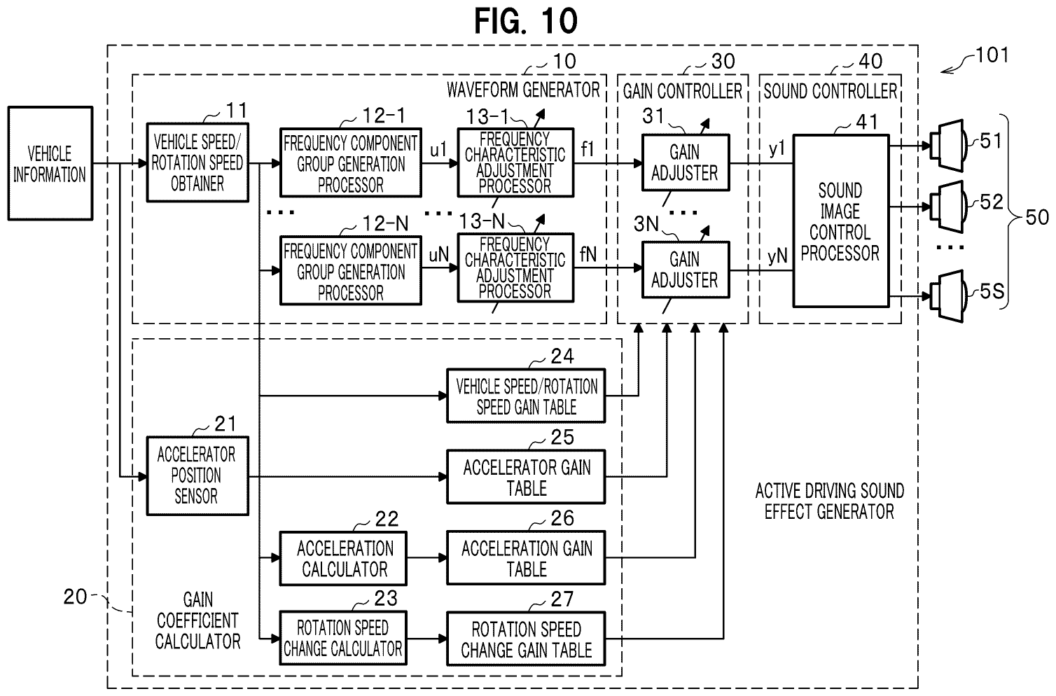

FIG. 10 is a block diagram showing an outline of a configuration of an active driving sound effect generator according to a second embodiment, mounted on a vehicle.

As shown in FIG. 10, an active driving sound effect generator 101 according to the second embodiment further includes frequency characteristic adjustment processors 13-1, . . . , 13-N in the waveform generator 10 of the active driving sound effect generator 100 according to the first embodiment. The frequency characteristic adjustment processors 13-1, . . . , 13-N will be also simply referred to as the frequency characteristic adjustment processors 13 when any one of them does not have to be specified.

The frequency characteristic adjustment processors 13-1, . . . , 13-N include band-pass filters to be applied to the signals u1, . . . , uN generated respectively by the corresponding frequency component group generation processors 12, . . . , 12-N (generation processors 124). Each of the band-pass filters is provided with a pass frequency band between the frequency of a signal generated at the upper limit value of the skip number ΔP in the skip table and the frequency of a signal generated at the lower limit value of the skip number ΔP.

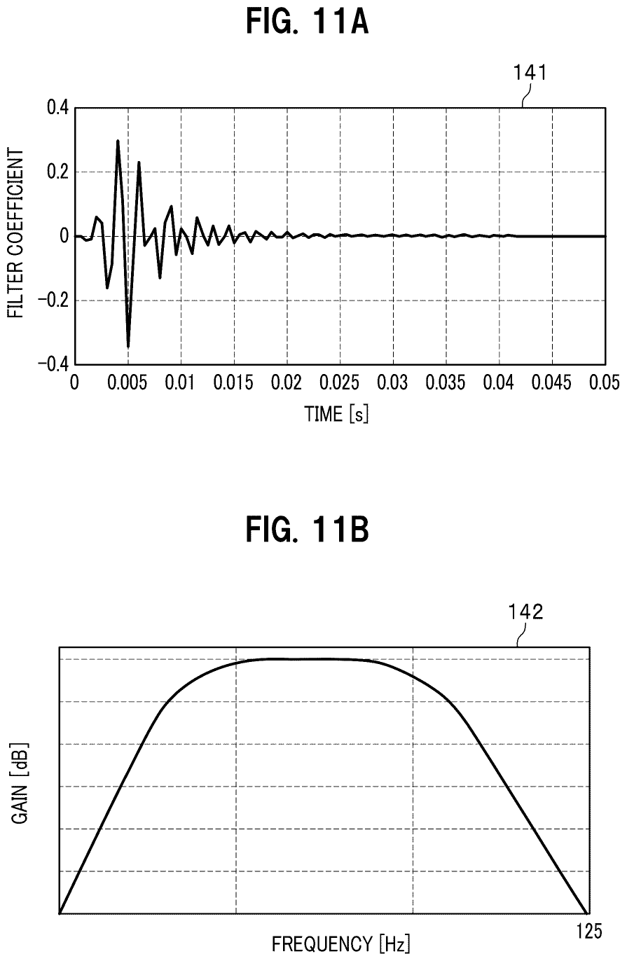

FIG. 11A is an explanatory diagram showing a coefficient of a band-pass filter included in the frequency characteristic adjustment processor. FIG. 11B is an explanatory diagram showing frequency characteristics based on the filter coefficient.

Each of the frequency characteristic adjustment processors 13-1, . . . , 13-N includes a band-pass filter to pass a predetermined frequency band based on a predetermined filter coefficient. In addition, the frequency characteristics shown in FIG. 11B are provided with a specific pass frequency band by combining a low-pass filter that attenuates frequency components higher than a predetermined cutoff frequency without attenuating low frequency components, and a high-pass filter that attenuates frequency components lower than a predetermined cutoff frequency without attenuating high frequency components.

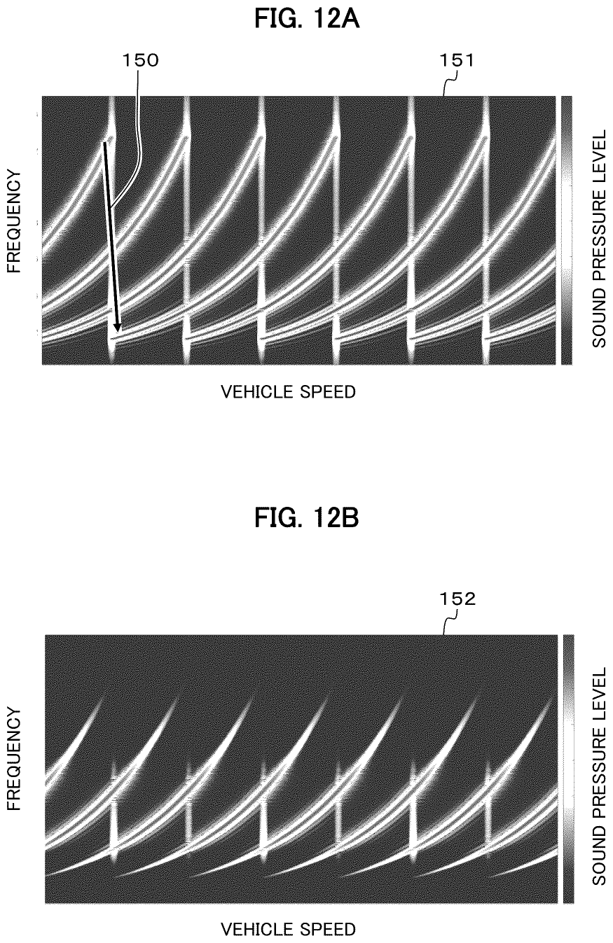

FIG. 12A is an explanatory diagram showing signals input to the frequency characteristic adjustment processors. As shown in FIG. 12A, in the signals u1, . . . , uN input to the frequency characteristic adjustment processors 13-1, . . . , 13-N, a frequency switchover is clearly (distinctly) output as shown by an arrow 150 in switching from the high frequency to the low frequency along with a change in the vehicle speed.

In contrast, FIG. 12B is an explanatory diagram showing signals output from the frequency characteristic adjustment processors. As shown in FIG. 12B, in signals f1, . . . , fN output from the frequency characteristic adjustment processors 13-1, . . . , 13-N, high frequency components and low frequency components are attenuated with the band-pass filter having the frequency characteristics as shown in FIG. 11B applied to the signals u1, . . . , uN input to the frequency characteristic adjustment processors 13-1, . . . , 13-N. Thus, in switchover from the high frequency component to the low frequency component, the signals f1, . . . , fN output from the frequency characteristic adjustment processors 13-1, . . . , 13-N can be faded out and faded in at these frequency components.

### [Operation of Active Driving Sound Effect Generator]

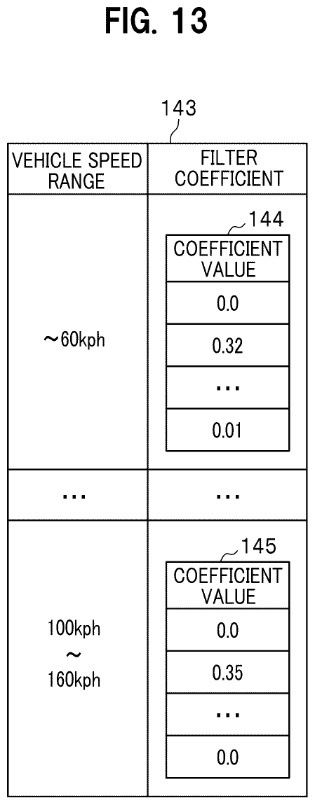

An operation of the active driving sound effect generator according to the second embodiment will be described in reference to FIG. 13.

FIG. 13 is an explanatory diagram showing a configuration to switch a filter coefficient of the active driving sound effect generator according to the second embodiment.

As shown in FIG. 13, each of the frequency characteristic adjustment processors 13 includes a filter coefficient setting table 143. The filter coefficient setting table 143 includes filter coefficients to be set to the band-pass filter depending on a vehicle speed range.

For example, when the vehicle speed of the vehicle 300 is up to 60 [kph], a data set 144 is applied and predetermined filter coefficients (0.0, 0.32, . . . , 0.01) are applied to the band-pass filter. When the vehicle speed of the vehicle 300 is in a range from 100 [kph] to 160 [kph], a data set 145 is applied and predetermined filter coefficients (0.0, 0.35, . . . , 0.00) are applied to the band-pass filter.

In this way, the frequency characteristic adjustment processors 13 switch the filter coefficients depending on the vehicle speed range and apply the band-pass filters to the signals u1, . . . , uN input to the frequency characteristic adjustment processors 13-1, . . . , 13-N.

As described above, the active driving sound effect generator 101 according to the second embodiment includes the band-pass filters in the waveform generator 10. The band-pass filters are applied to the signals u1, . . . , uN generated by the waveform generator 10. The band-pass filters are each provided with a pass frequency band between the frequency of a signal generated at the upper limit value in the skip table 123 and the frequency of the signal generated at the lower limit value in the skip table 123.

With this configuration, the active driving sound effect generator 101 according to the second embodiment is able to apply the band-pass filters to the signals u1, . . . , uN input to the frequency characteristic adjustment processors 13-1, . . . , 13-N, thereby making it possible to generate a natural sound effect by eliminating the feeling of a frequency switchover along with a change in the vehicle speed.

What is claimed is:

1. An active driving sound effect generator mounted on a vehicle, comprising:
a waveform generator configured to generate a signal from a waveform table depending on vehicle information;
a speaker configured to output the signal generated by the waveform generator, wherein
the waveform table is a cyclic waveform table in which an end point and a start point of the waveform table are continuous and contains a plurality of frequency components.

2. The active driving sound effect generator according to claim 1, wherein
the waveform generator includes a plurality of the waveform tables, and generate a signal from each of the plurality of waveform tables, and
the active driving sound effect generator further comprises a plurality of gain adjusters respectively corresponding to signals generated from the plurality of waveform tables.

3. The active driving sound effect generator according to claim 2, wherein
the waveform generator includes a low frequency waveform table containing relatively many low frequency components and a high frequency waveform table containing more high frequency components than the low frequency waveform table does,
the vehicle information indicates a vehicle speed or a rotation speed of a power unit,
when the vehicle speed or the rotation speed is relatively low, a gain for the low frequency waveform table is increased, and
when the vehicle speed or the rotation speed is relatively high, a gain for the high frequency waveform table is increased.

4. The active driving sound effect generator according to claim 1, wherein
the waveform generator includes a plurality of the waveform tables, and
the plurality of waveform tables are switchable in response to a user's operation.

5. The active driving sound effect generator according to claim 4, wherein
the plurality of waveform tables include a waveform table added by a user's operation, and
the waveform generator is capable of switching a waveform table from which to generate the signal to the added waveform table among the plurality of waveform tables.

6. The active driving sound effect generator according to claim 1, wherein
the waveform generator includes a skip table from which a skip number for a read position is obtained based on the vehicle information, and a generation processor configured to generate a signal to be input to the speaker by reading a signal in the waveform table at a position specified by a sum of a previous read position in the waveform table and the obtained skip number.

7. The active driving sound effect generator according to claim 6, wherein
a plurality of the skip tables are provided, and
the skip tables are switched according to a user's selection operation.

8. The active driving sound effect generator according to claim 6, wherein
the vehicle information indicates the vehicle speed or the rotation speed of the power unit, and
in the skip table, based on an increase in the vehicle speed or the rotation speed, a value is exponentially increased from a lower limit value to an upper limit value and is returned to the lower limit value when reaching the upper limit value.

9. The active driving sound effect generator according to claim 8, wherein
the waveform generator includes a band-pass filter to be applied to the signal generated by the generation processor, and
the band-pass filter is provided with a pass frequency band between a frequency of a signal generated at the upper limit value in the skip table and a frequency of a signal generated at the lower limit value in the skip table.
